(19) United States
(12) Patent Application Publication
(10) Pub. No.: US 2021/0384391 A1
(43) Pub. Date: Dec. 9, 2021

(54) OPTICAL MEMBER WITH ADHESIVE LAYER AND LIGHT EMITTING DEVICE

(71) Applicant: AGC Inc., Tokyo (JP)

(72) Inventor: Takenori SOMEYA, Tokyo (JP)

(73) Assignee: AGC Inc., Tokyo (JP)

(21) Appl. No.: 17/404,042

(22) Filed: Aug. 17, 2021

Related U.S. Application Data
(63) Continuation of application No. PCT/JP2020/007184, filed on Feb. 21, 2020.

(30) Foreign Application Priority Data
Feb. 28, 2019 (JP) 2019-036763

(51) Int. Cl. H01L 33/58; G02B 7/02

(52) U.S. Cl. CPC H01L 33/58; G02B 7/025

(57) ABSTRACT

An optical member with the adhesive layer includes the optical member formed of inorganic glass through which light passes; and the adhesive layer formed of an inorganic material or a metal oxide. The inorganic material includes inorganic glass or nitride.

### CROSS-REFERENCE TO RELATED APPLICATION

The present application is a continuation application of International Application No. PCT/JP2020/007184, filed Feb. 21, 2020, which claims priority to Japanese Patent Application No. 2019-036763 filed Feb. 28, 2019. The contents of these applications are incorporated herein by reference in their entirety.

### BACKGROUND OF THE INVENTION

### 1. Field of the Invention

The disclosure herein generally relates to an optical member with an adhesive layer and a light-emitting device.

### 2. Description of the Related Art

A light-emitting diode element (LED element) having a flip-chip structure or a vertical type structure in order to improve an efficiency for extracting light emitted from the LED element has been known. However, light extracted to the outside of the LED element to be provided for use is only a part of the light emitted from the LED element, and there is a demand for a utilization efficiency of light to be further enhanced. In particular, for an ultraviolet-ray emitting diode, in which an emission wavelength is an ultraviolet ray wavelength, such a low light extraction efficiency is a problem that hinders widespread use of ultraviolet-ray emitting diodes. Ultraviolet-ray emitting diodes are used, depending on the emission wavelength, in various applications including a curing process of an ultraviolet-curing resin, treatment of skin diseases, sterilization of viruses and pathogenic bacteria, and the like.

For such a problem, a variety of techniques for enhancing the light extraction efficiency have been developed. For example, a photonic crystal having an uneven structure on a light emitting surface of an LED element by etching, so as to extract a part of totally reflected light to the outside of the LED element has been proposed (See, for example, Japanese Patent No. 6349036). However, with the technique disclosed in Japanese Patent No. 6349036, a total reflection cannot be prevented from occurring at the light emitting surface and an air interface, and the light extraction efficiency is not sufficiently enhanced.

Moreover, a variety of techniques of arranging optical members on LED elements have been proposed. For example, a technique using a hemispherical lens of sapphire for the optical member (See, for example, Japanese Patent No. 6230038), and a technique using a spinel sintered compact for the optical member (See, for example, Wo 2018/066636) have been proposed. However, sapphire, which is extremely hard and inferior in workability, increases a manufacturing cost. Because the spinel is restricted in a machining shape, a degree of freedom for the optical member is low. Moreover, adhesion of the above-described optical members has not been studied much.

Furthermore, an optical member formed of fluororesin has been proposed (See, for example, WO 2017/208535). However, due to the extremely low refractive index of fluororesin, the light extraction efficiency cannot be sufficiently enhanced.

Moreover, a structure, in which an LED element and an optical member are in contact with each other via resin, has been proposed (See, for example, Japanese Unexamined Patent Application Publication No. 2018-67630 and WO 2016/190207). However, such resin may be deteriorated by light emitted from the LED element, and consequently a transmittance may decrease and the resin may become damaged.

Moreover, a structure in which an LED element and an optical member are bonded to each other with fluorine containing glass has been proposed (See, for example, Japanese Unexamined Patent Publication No. 2018-35046). However, because glass containing fluorine is inferior in a humidity resistance and a water resistance, a fogging or a white turbidity may occur and a transmittance may decrease. Moreover, fluorine greatly lowers the refractive index and makes it difficult to enhance the light extraction efficiency.

### SUMMARY OF THE INVENTION

### Problem to be Solved by the Invention

As described above, various techniques for combining an optical member with an LED element to enhance a light extraction efficiency have been proposed. However, with the conventional techniques, manufacturing costs might increase and the life of product become shorter.

In view of the above-described problem, the present application aims at providing a light emitting device, for which a manufacturing cost can be reduced, and which has an excellent life of product; and an optical member with an adhesive layer required in manufacturing the light emitting device. Furthermore, the present application also aims at providing a light emitting device provided with an LED element, especially a UV-LED element emitting an ultraviolet ray, with an enhanced light extraction efficiency; and an optical member with an adhesive layer required in manufacturing the light emitting device.

### Means to Solve the Problem

Inventors of the present disclosure studied diligently in order to solve the above-described problem, and found, as a result of their study, that when, in a light emitting device, in which an LED element and an optical member are combined together, the optical member is formed of inorganic glass, and the LED element and the optical member are bonded to each other via an adhesive formed of an inorganic material, a light emitting device, in which a manufacturing cost is reduced and deterioration due to light emitted from the LED element is suppressed, and an optical member with an adhesive layer required in manufacturing the light emitting device can both be obtained, and from this the inventors completed the present disclosure.

That is, an optical member with an adhesive layer according to the present disclosure includes the optical member formed of inorganic glass through which light passes; and the adhesive layer formed of an inorganic material or a metal oxide, the organic material including inorganic glass or nitride. Moreover, a light emitting device according to the present disclosure includes the optical member with the adhesive layer of the present disclosure; a substrate; an LED element arranged on the substrate, the adhesive layer being arranged between the LED element and the optical member.

Preferably, for the LED element a UV-LED element emitting an ultraviolet ray is used, and a predetermined optical member with an excellent transmittance for an ultraviolet ray and an adhesive layer of an inorganic material are arranged.

### Effect of Invention

According to the present disclosure, a light emitting device, in which a manufacturing cost is reduced and deterioration due to light emitted from the light emitting device is suppressed, and an optical member with an adhesive layer required in manufacturing the light emitting device can be provided. Moreover, a light emitting device provided with an LED element, especially a UV-LED element emitting an ultraviolet ray, with an enhanced light extraction efficiency; and an optical member with an adhesive layer required in manufacturing the light emitting device can be provided.

### BRIEF DESCRIPTION OF THE DRAWINGS

Other objects and further features of the present disclosure will be apparent from the following detailed description when read in conjunction with the accompanying drawings, in which:

FIG. 1 is a cross-sectional view depicting a schematic configuration diagram of an example of a light emitting element according to an embodiment of the present application;

FIG. 2A is a cross-sectional view depicting a variation of the light emitting element according to the embodiment of the present application;

FIG. 2B is a cross sectional view depicting another variation of the light emitting element according to the embodiment of the present application;

FIG. 2C is a cross sectional view depicting yet another variation of the light emitting element according to the embodiment of the present application;

FIG. 2D is a cross sectional view depicting still another variation of the light emitting element according to the embodiment of the present application;

FIG. 2E is a cross sectional view depicting yet another variation of the light emitting element according to the embodiment of the present application;

FIG. 2F is a cross sectional view depicting still another variation of the light emitting element according to the embodiment of the present application;

FIG. 2G is a cross sectional view depicting yet another variation of the light emitting element according to the embodiment of the present application;

FIG. 2H is a cross sectional view depicting still another variation of the light emitting element according to the embodiment of the present application; and

FIG. 3 is a diagram showing a detection range of light in estimating an output of light emitted from a light emitting device according to a practical example of the present application.

### DESCRIPTION OF THE PREFERRED EMBODIMENTS

In the following, a light emitting device according to the present application will be described in detail with reference to an embodiment.

### [Light Emitting Device]

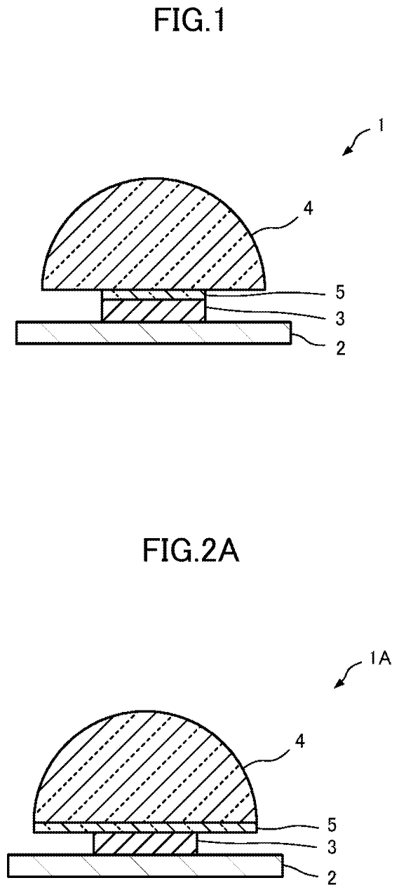

The light emitting device according to the embodiment of the present application includes, for example, as shown in FIG. 1, a light emitting device 1 including a substrate 2; an LED element 3 arranged on the substrate 2; an optical member 4 provided on the LED element 3 and formed of inorganic glass through which light emitted from the LED element 3 is passed so as to be emitted to the outside; and an adhesive layer 5 formed of an inorganic material and arranged between the LED element 3 and the optical member 4.

FIG. 1 is a cross-sectional view depicting a schematic configuration of the light emitting device 1. The light emitting device 1 has a flip-chip structure or a vertical structure. In the following, each member will be described with reference to FIG. 1.

### (Substrate)

The substrate 2 according to the embodiment of the present application is a supporting substrate for arranging the LED element 3, or the like, which will be described below, on a surface thereof. For the substrate 2, a substrate conventionally used in a light emitting device can be used without being restricted.

The substrate 2 includes, for example, a substrate formed of ceramics such as alumina, aluminum nitride, or LTCC (Low-temperature Co-fired Ceramics), or resin such as nylon, epoxy, or LCP (Liquid Crystal Polymer).

Although not shown in the drawings, the substrate 2 is provided with an electrode which is configured so as to be electrically connected to the LED element 3.

### (LED Element)

For the LED element 3 according to the embodiment of the present application, an LED element conventionally used in a light emitting device can be used without being restricted. The LED element 3 includes, for example, an infrared LED element, a visible light LED element, a UV-LED element, or the like. In particular, a UV-LED element is preferably used.

In the specification of the present application, the UV-LED element refers to an element that emits light with a wavelength of greater than or equal to 200 nm and less than or equal to 400 nm as an ultraviolet ray. The UV-LED element can be manufactured, for example, by growing a III-V group semiconductor, such as AlInGaN, InGaN, or AlGaN, on a base of sapphire, aluminum nitride (AlN), or the like, by using a Metal Organic Chemical Vapor Deposition (MOCVD) method, a Hydride Vapor Phase Epitaxy (HVPE) method, or the like.

In the case where the light emitting device has the flip-chip structure, a light is emitted from a surface on a side opposite to the surface on which a semiconductor layer and an electrode of the LED element are arranged. In the case where the light emitting device has the vertical structure, because after a semiconductor layer is formed on a base of sapphire, or the like a part of the base of the sapphire, or the like is removed, a light emitting surface is an exposed semiconductor layer or a transparent electrode formed on the semiconductor layer. Thus, a material on the light emitting surface of the LED element is sapphire, aluminum nitride (AlN), or the like (flip-chip structure), or a semiconductor of AlInGaN, InGaN, AlGaN, or the like or the transparent electrode of ITO, ZnO, SnO₂, Ga₂O₃, or the like (vertical structure). In either of the structures, the material on the light emitting surface has a high refractive index.

### (Optical Member)

The optical member 4 is formed of inorganic glass, and allows light emitted from the LED element 3 to pass through so as to be emitted the light to the outside. The optical member 4 may have any shape, as long as the above-described function is performed. For example, the optical member 4 may have a shape of a lens, a lens array, or the like. In particular, the optical member 4 preferably has a shape of a convex lens with a spherical surface or an aspherical surface. FIG. 1 shows the optical member 4 having a shape of a convex lens. The optical member formed of inorganic glass can be easily processed into various shapes as compared with a crystalline material such as sapphire or spinel. Thus, the manufacturing cost can be reduced, and thus the optical member is suitable for mass-production. Furthermore, the optical member formed of inorganic glass is unlikely to deteriorate even if the optical member is exposed to light with a high intensity emitted from the LED element or light with short wavelengths, such as ultraviolet rays, for a long time, or even if the temperature rises due to the heat from the LED element. Thus, the optical member is suitable for providing long-life LED elements.

Because the light emitting surface of the LED element 3 is formed of a high refractive index material, the light extraction efficiency can be significantly enhanced when the optical member 4 is formed of a high refractive index glass material. Thus, a refractive index n_{d(O)} for a d-line (587.6 nm) of the high refractive index glass material forming the optical member 4 is preferably greater than or equal to 1.5, more preferably greater than or equal to 1.6, further preferably greater than or equal to 1.65, and especially preferably greater than or equal to 1.7.

Light emitted from the LED element passes through the optical member, which is processed into a shape of a lens, or the like, and emitted to the outside of the light emitting device. Thus, when the inorganic glass material forming the optical member 4 has a high transmittance at a wavelength of light emitted from the LED element 3, a loss of light can be suppressed and thereby the light extraction efficiency can be further enhanced. A length of a part in the optical member in which the light passes through is about 0.5 mm to 5 mm. An absorption coefficient α of the inorganic glass material at the wavelength of light emitted from the LED element is less than or equal to 0.2 (mm⁻¹), preferably less than or equal to 0.15 (mm⁻¹), and more preferably less than or equal to 0.1 (mm⁻¹).

A glass transition temperature T_{g} (° C.) of the glass material forming the optical member 4 is preferably high so that the shape of the optical member 4 does not become deformed even when the optical member 4 is heated during the manufacturing process, such as during bonding of the LED element 3 to the optical member 4. The glass transition temperature T_{g} (° C.) is preferably greater than or equal to 350° C., more preferably greater than or equal to 400° C., and especially preferably greater than or equal to 500° C.

The inorganic glass material used in the embodiment of the present application includes, for example, borosilicate glass, silica glass, phosphate glass, fluorophosphate glass, or the like.

Borosilicate glass mainly includes silicon dioxide (SiO₂) and diboron trioxide (B₂O₃) , and includes dialuminum trioxide (Al₂O₃), an alkaline earth metal oxide (MgO, CaO, SrO, or BaO), an alkali metal oxide (Li₂O, Na₂O, or K₂O), other metal oxides, or the like.

Phosphate glass mainly includes diphosphorous pentaoxide (P₂O₅), and includes dialuminum trioxide (Al₂O₃), an alkaline earth metal oxide (MgO, CaO, SrO, or BaO), an alkali metal oxide (Li₂O, Na₂O, or K₂O), other metal oxides, or the like.

The optical member 4 may be provided with an antireflection film formed on the surface thereof. For the antireflection film, for example, a single layered film or a multi-layered film of a dielectric of SiO₂, MgF₂, Al₂O₃, HfO₂, ZrO₂, Ta₂O₅, or the like is used. According to the antireflection film formed on the surface of the optical member 4, a Fresnel reflection is reduced on the surface of the optical member 4, and thus the light extraction efficiency can be further enhanced.

### (Adhesive Layer)

The adhesive layer 5 of the embodiment of the present application is formed of an inorganic material, and bonds the LED element 3 and the optical member 4 to each other. Moreover, the bonding layer 5 is formed of a material that enables light transmitted from the LED element 3 to pass through and thereby guide the light to the inside of the optical member 4.

The bonding layer 5 mainly includes an inorganic material such as nitride or inorganic glass. Thus, the bonding layer 3 is prevented from deteriorating by light emitted from the LED element 3, especially even in the case of ultraviolet rays, as compared with a resin, or the like, and long-life products can be provided.

The inorganic glass material used for the adhesive layer 5 includes, for example, glass containing a multicomponent oxide, Na₂SiO₃ glass obtained by heating water glass (Na₂SiO₃), or the like. The inorganic glass preferably does not contain fluorine. When the inorganic glass contains fluorine, a water resistance tends to be degraded, and the refractive index tends to decrease.

Nitride used for the adhesive layer 5 includes SiN, AlN, or the like.

The optical member 4 is bonded to the light emitting surface of the LED element 3 via the adhesive layer 5. Thus, when the inorganic glass material forming the adhesive layer 5 has a high transmittance at a wavelength of light emitted from the LED element 3, a loss of light can be suppressed and thereby the light extraction efficiency can be further enhanced. A length of a part in the adhesive layer 5 in which the light passes through is about 50 nm to 0.2 mm. An absorption coefficient a of the inorganic material forming the adhesive layer 5 at the wavelength of light emitted from the LED element 3 is less than or equal to 8 (mm⁻¹) , preferably less than or equal to 5 (mm⁻¹), and more preferably less than or equal to 3 (mm⁻¹). Because the adhesive layer 5 is prepared separately from the optical member 4, the adhesive layer 5 can be made thin, and thus a loss of light due to absorption can be suppressed.

When the thickness of the adhesive layer 5 is less than the wavelength of the light emitted from the LED element 3, evanescent light, generated by light which reaches the light emission surface of the LED element 3, reaches the optical member 4 bonded to the surface via the adhesive layer 5, and thereby the light extraction efficiency is enhanced. A ratio of the thickness d of the adhesive layer 5 to the wavelength λ of the light emitted from the LED element 3 (d/λ) is less than 1, preferably less than 0.5, and more preferably less than 0.4.

In the case where the thickness d of the adhesive layer 5 is greater than or equal to the wavelength λ of the light emitted from the LED element 3, when the refractive index of the adhesive layer 5 is too low, the light extraction efficiency cannot be sufficiently enhanced due to a total reflection at an interface between the light emission surface of the LED element 3 and the adhesive layer 5. When the ratio of the thickness d to the wavelength λ is greater than or equal to 1, the refractive index n_{d(A)} for a d-line of the inorganic material forming the adhesive layer 5 is greater than or equal to 1.5, preferably greater than or equal to 1.6, more preferably greater than or equal to 1.65, and especially preferably greater than or equal to 1.7.

In this case, by reducing a difference between the refractive indices of the optical member 4 and the adhesive layer 5, the total reflection and the Fresnel reflection at the interface can be prevented from occurring, and thereby the light extraction efficiency can be further enhanced. An absolute value of the difference between the d-line refractive indices of the optical member 4 and the adhesive layer 5, Δn_{d} (=|n_{d(O)}−n_{d(A)}|), is preferably less than or equal to 0.2, more preferably less than or equal to 0.15, and especially preferably less than or equal to 0.1.

The light emitting surface of the LED element 3 may be planar, or a fine unevenness may be formed on the surface. When a large unevenness is present on the light emitting surface of the LED element 3, a gap is formed at an interface between the light emitting surface and the adhesive layer 5, and light emitted from the LED element 3 is scattered. Consequently, the light extraction efficiency might decrease. Thus, the light emitting surface of the LED element 3 is preferably planar, and more preferably the surface is not a rough surface.

### (Example of Configuration of Light Emitting Device)

In the following, a preferred configuration of the light emitting device will be described with an example, in which an LED element emitting an ultraviolet ray (UV-LED element) is used for the LED element 3.

When the UV-LED is arranged on the substrate in the flip-chip structure, typically the light emitting surface is formed of a material that is sapphire, aluminum nitride (AlN), or the like. When the optical member 4 is arranged, bonding to the above-described material is to be taken into consideration.

Both the optical member 4 and the adhesive layer 5 are preferably formed of ultraviolet ray-transmitting glass having an excellent transmittance for an ultraviolet ray. For the ultraviolet ray-transmitting glass used here, known ultraviolet ray-transmitting glass can be used without being restricted.

The ultraviolet ray-transmitting glass includes, for example, a glass material containing a multicomponent inorganic oxide having an excellent transmittance for light with a wavelength of an ultraviolet ray region, as described below.

A composition system of the above-described ultraviolet ray-transmitting glass includes specifically a glass in which a matrix composition is borosilicate glass, silica glass, phosphate glass, fluorophosphate glass, or the like.

Because the ultraviolet ray transmittance of the above-described glass decreases when a content of iron component (FeO and Fe₂O₃) is large, the content of the iron component in the glass is preferably small. Iron is present in the glass as a trivalent iron ion with a valence number of 3 (Fe³⁺) or a divalent iron ion with a valence number of 2 (Fe²⁺). The total content of iron oxide, obtained by converting iron contained in the glass into diiron trioxide (Fe₂O₃) , will be denoted by T-Fe₂O₃. The content T-Fe₂O₃ of the ultraviolet ray-transmitting glass according to the embodiment of the present application is less than or equal to 10 mass ppm, preferably less than or equal to 5 mass ppm, more preferably less than or equal to 2.5 mass ppm, especially preferably less than or equal to 2 mass ppm, and most preferably less than or equal to 1 mass ppm. The smaller the content is, the more preferable the glass is. The above-described iron component was mainly introduced into glass from impurities contained in a glass raw material, other than an admixture of an iron content during a dissolution process.

In particular, for the LED element emitting an ultraviolet ray with a wavelength of 200 nm-400 nm, the content T-Fe₂O₃ in the inorganic glass transparent in the ultraviolet ray region is less than or equal to 5 mass ppm, preferably less than or equal to 2 mass ppm, more preferably less than or equal to 1.5 mass ppm, especially preferably less than or equal to 1 mass ppm, and most preferably less than or equal to 0.9 mass ppm. The smaller the content is, the more preferable the glass is.

Moreover, in order to further decrease the absorption coefficient in the ultraviolet ray region, it is preferable to decrease the valence number of the iron component contained in the glass from 3 (Fe³⁺) to 2 (Fe²⁺). By reducing trivalent iron ions Fe³⁺ to divalent iron ions Fe²⁺ in the glass, the content of trivalent iron ion Fe³⁺, which absorbs an ultraviolet ray, can be decreased, the absorption coefficient in the ultraviolet ray region can be decreased, and thereby the ultraviolet ray transmittance can be enhanced. The method of controlling valence numbers of iron ions, as described above, will be described later in detail, and can be performed by adding a component to serve as a reducing agent to a glass raw material or a glass cullet during a glass melting process, by making an atmosphere non-oxidizable in the glass melting process, or the like. For the reducing agent, organic matter, fluoride, metal such as Si, or tin oxide is used. The non-oxidizing atmosphere can be provided by replacing air in a dissolution furnace with Ar, N₂, CO₂, or the like. In this case, a content of a trivalent iron ion Fe³⁺ contained in a glass molded article obtained according to the above-described process is further decreased. The content of a trivalent iron ion Fe³⁺ can be measured by an electron spin resonance (ESR) method. When the content of Fe³⁺ is small, a trivalent iron ion Fe³⁺ intensity measured by the ESR is also small. By selecting the kind of a reducing agent, an amount of the reducing agent, and an atmosphere for dissolution, so that the Fe³⁺ intensity is preferably less than or equal to 0.0400, more preferably less than or equal to 0.0300, further preferably less than or equal to 0.0200, and especially preferably less than or equal to 0.0150, a glass exhibiting an excellent transparency also in a shorter wavelength region can be obtained. When the content T-Fe₂O₃ is large, it is preferable to decrease an intensity of Fe³⁺ by enhancing the reduction property for the glass. When the content T-Fe₂O₃ is small, the content of Fe³⁺ is also small, and thus the intensity of Fe³⁺ is small.

In typical glass, various transition metal oxides can be contained as glass components. In the ultraviolet ray-transmitting glass used in the embodiment of the present application, in order to enhance the ultraviolet ray transmittance, contents of components that absorb light in the ultraviolet ray region are preferably small. In order to enhance a transmittance in the near-ultraviolet region, for example, each of contents (by mol % in terms of oxide) of dibismuth trioxide (Bi₂O₃), titanium dioxide (TiO₂), tungsten trioxide (WO₃) and digadolinium trioxide (Gd₂O₃) in the ultraviolet ray-transmitting glass is preferably less than or equal to 3 mol %, or more preferably less than or equal to 1 mol %, and it is especially preferable that those components are substantially not contained.

Moreover, because tin oxides (SnO and SnO₂) are also components that absorb light in the ultraviolet ray region, each tin oxide component is preferably less than or equal to 3 mol %. On the other hand, tin oxides (SnO and SnO₂) can be used by appropriate amounts as reducing agents for enhancing the transmittance.

In order to further enhance a transmittance in the deep-ultraviolet region, in addition to the above-described restriction, each of contents of diniobium pentaoxide (Nb₂O₅) and ditantalum pentaoxide (Ta₂O₅) in the ultraviolet ray-transmitting glass is preferably less than or equal to 3 mol %, more preferably less than or equal to 1 mol %, and it is especially preferable that those components are substantially not contained. In the specification of the present application, “substantially not contained” refers to being not made to contain intentionally, except for a case of being inevitably introduced arising from impurities in the glass raw material, and specifically being less than or equal to 0.01 mol %.

Specifically, a glass composition of the above-described ultraviolet ray-transmitting glass preferably includes, for example, a glass composition 1 or a glass composition 2, which will be described below. The glass composition 1 is a composition with a high refractive index n_{d(O)} of greater than or equal to 1.7, and the glass composition 2 is a composition with a low refractive index n_{d(O)} of less than 1.7.

### (Glass Composition 1)

The glass composition 1 is a composition containing, by mol % in terms of an oxide, B₂O₃: 10-80%, SiO₂: 0-25%, La₂O₃: 2-32%, and Y₂O₃: 0-20%.

In the glass composition 1, diboron trioxide (B₂O₃) is an essential component of the glass composition 1, and this component forms a skeleton of glass, enhances a stability of glass, and enhances the ultraviolet ray transmittance. Glass with a B₂O₃ content of greater than or equal to 10 mol % (in the following, mol % will be abbreviated simply as %) is stable. The B₂O₃ content is preferably greater than or equal to 20%, more preferably greater than or equal to 30%, and especially preferably greater than or equal to 40%. On the other hand, with the B2O₃ content of less than or equal to 80%, an occurrence of phase splitting of glass is inhibited. The B₂O₃ content is preferably less than or equal to 75%, and more preferably less than or equal to 70%.

In the glass composition 1, silicon dioxide (SiO₂) is an optional component of the glass composition 1, and this component forms a skeleton of glass, similarly to B₂O₃, enhances a stability of glass, enhances a devitrification resistance of glass, and suppresses an occurrence of a phase splitting of glass. With a SiO₂ content of less than or equal to 25%, an occurrence of undissolved residue is inhibited during the dissolution process. The SiO₂ content is preferably less than or equal to 20%, and more preferably less than or equal to 18%. On the other hand, in order to lower a liquidus temperature to suppress the occurrence of a devitrification, and enhance chemical durability, SiO₂ is preferably contained. The SiO₂ content is more preferably greater than or equal to 1%, especially preferably greater than or equal to 3%, and most preferably greater than or equal to 5%.

In the glass composition 1, dilanthanum trioxide (La₂O₃) is an essential component of the glass composition 1, and this component maintains a high ultraviolet ray transmittance while enhancing a refractive index. Glass with a La₂O₃ content of greater than or equal to 2% is provided with a high refractive index, as desired. The La₂O₃ content is preferably greater than or equal to 5%, and more preferably greater than or equal to 6%. On the other hand, when the La₂O₃ content is less than or equal to 32%, a liquidus temperature increases are inhibited, and the occurrence of a devitrification can be suppressed. The La₂O₃ content is preferably less than or equal to 28%, more preferably less than or equal to 25%, and especially preferably less than or equal to 22%.

In the glass composition 1, diyttrium trioxide (Y₂O₃) is a component of the glass composition 1, and this component maintains a high ultraviolet ray transmittance while enhancing a refractive index, and in coexistence with La₂O₃ lowers the liquidus temperature to improve the devitrification resistance. When a Y₂O₃ content is less than or equal to 20%, a dissolution temperature and a molding temperature increases are inhibited, the liquidus temperature increases are inhibited, and the occurrence of a devitrification can be suppressed. The Y₂O₃ content is preferably less than or equal to 15%, more preferably less than or equal to 13%, and especially preferably less than or equal to 10%. In order to enhance the refractive index, Y₂O₃ is preferably contained in the glass, the Y₂O₃ content is more preferably greater than or equal to 2%, especially preferably greater than or equal to 4%, and most preferably greater than or equal to 5%.

Furthermore, the glass composition 1 may also contain the following components.

In the glass composition 1, dilithium oxide (Li₂O) is an optional component of the glass composition 1, and this component improves meltability of glass, and lowers the glass transition temperature and a softening temperature. When a Li₂O content is less than or equal to 15%, the refractive index can be decreases are inhibited and an increase in the liquidus temperature can be suppressed. The Li₂O content is preferably less than or equal to 13%, more preferably less than or equal to 10%, and especially preferably less than or equal to 5%. In the case of performing hot forming for glass in the post processing, the glass transition temperature is to be appropriately lowered. For the process, Li₂O is preferably contained in the glass. The Li₂O content is more preferably greater than or equal to 1%, and especially preferably greater than or equal to 2%.

In the glass composition 1, disodium oxide (Na₂O) is an optional component of the glass composition 1, and this component improves meltability of glass, and lowers the glass transition temperature and the softening temperature. When a Na₂O content is less than or equal to 15%, the refractive index decreases are inhibited and an increase in the liquidus temperature can be suppressed. The Na₂O content is preferably less than or equal to 13%, more preferably less than or equal to 10%, and especially preferably less than or equal to 5%.

In the glass composition 1, dipotassium oxide (K₂O) is an optional component of the glass composition 1, and this component improves meltability of glass, and lowers the glass transition temperature and the softening temperature. When a K₂O content is less than or equal to 15%, the refractive index decreases are inhibited and an increase in the liquidus temperature can be suppressed. The K₂O content is preferably less than or equal to 13%, more preferably less than or equal to 10%, and especially preferably less than or equal to 5%.

In the glass composition 1, zinc oxide (ZnO) is an optional component of the glass composition 1, and this component improves a meltability of glass, and lowers the glass transition temperature and the softening temperature. A large amount of ZnO can be contained in the glass while maintaining the devitrification resistance. When a ZnO content is less than or equal to 35%, the refraction index decreases are inhibited. The ZnO content is preferably less than or equal to 33%, more preferably less than or equal to 25%, and especially preferably less than or equal to 20%.

In the glass composition 1, magnesium oxide (MgO) is an optional component of the glass composition 1, and this component suppresses a phase splitting of glass from occurring, and improves a meltability of glass. When a MgO content is less than or equal to 15%, the refractive index decreases are inhibited and an increase in the liquidus temperature can be suppressed. The MgO content is preferably less than or equal to 13%, more preferably less than or equal to 10%, and especially preferably less than or equal to 5%.

In the glass composition 1, calcium oxide (CaO) is an optional component of the glass composition 1, and this component suppresses a phase splitting of glass from occurring, and improves a meltability of glass. When a CaO content is less than or equal to 15%, the refractive index decreases are inhibited and an increase in the liquidus temperature can be suppressed. The CaO content is preferably less than or equal to 13%, more preferably less than or equal to 10%, and especially preferably less than or equal to 5%.

In the glass composition 1, strontium oxide (SrO) is an optional component of the glass composition 1, and this component suppresses a phase splitting of glass from occurring, and improves a meltability of glass. When a SrO content is less than or equal to 15%, the refractive index decreases are inhibited and an increase in the liquidus temperature can be suppressed. The SrO content is preferably less than or equal to 13%, more preferably less than or equal to 10%, and especially preferably less than or equal to 5%.

In the glass composition 1, barium oxide (BaO) is an optional component of the glass composition 1, and this component suppresses a phase splitting of glass from occurring, and improves a meltability of glass. When a BaO content is less than or equal to 15%, the refractive index decreases are inhibited and an increase in the liquidus temperature can be suppressed. The BaO content is preferably less than or equal to 13%, more preferably less than or equal to 10%, and especially preferably less than or equal to 5%.

In the glass composition 1, zirconium dioxide (ZrO₂) is an optional component of the glass composition 1, and this component can increase the refractive index while maintaining the high ultraviolet ray transmittance, and improve a devitrification resistance. When a ZrO₂ content is less than or equal to 15%, degradation of the devitrification resistance due to an excessive content of ZrO₂ can be suppressed. The ZrO₂ content is preferably less than or equal to 13%, and more preferably less than or equal to 10%.

In the glass composition 1, dialuminum trioxide (Al₂O₃) is an optional component of the glass composition 1, and this component improves a chemical durability, and suppresses an occurrence of a phase splitting of glass. When an Al₂O₃ content is less than or equal to 10%, the refractive index decreases are inhibited, and an increase in the liquidus temperature is suppressed. The Al₂O₃ content is preferably less than or equal to 5%, more preferably less than or equal to 3%, and especially preferably less than or equal to 1%.

In the glass composition 1, because diantimony trioxide (Sb₂O₃) oxidizes glass, a Sb₂O₃ content is preferably small in order to enhance the deep-ultraviolet ray transmittance, e.g. less than or equal to 0.1%, more preferably less than or equal to 0.05%, and further preferably the Sb₂O₃ is substantially not contained.

In the glass composition 1, in order to reduce an environmental load, preferably lead oxide (PbO) and diarsenic trioxide (As₂O₃) are substantially not contained, except for inevitable contaminating. Fluorine (F) is also preferably substantially not contained in the glass, in order to suppress a variation of optical characteristics or a striae, because fluorine exhibits a volatility. Moreover, because fluorine (F) component reduces the refractive index significantly, preferably fluorine (F) is substantially not contained in the case of enhancing the refractive index of the optical member.

The feature of the optical characteristic of the glass composition 1 is that the refractive index n_{d(O)} is greater than or equal to 1.7. The higher the refractive index is, i.e. the closer to the refractive index of the material of the light emitting surface of the LED element the refractive index of the optical member is, the more suitable the glass composition 1 is for enhancing the light extraction efficiency. The refractive index n_{d(O)} is preferably greater than or equal to 1.71, more preferably greater than or equal to 1.72, and especially preferably greater than or equal to 1.73.

### (Glass Composition 2)

The glass composition 2 is a composition containing, by mol % in terms of oxide, B₂O₃+SiO₂+P₂O₅: 40% to 90%, Li₂O+Na₂O+K₂O: 0% to 30%, and MgO+CaO+SrO+BaO: 0% to 20%.

In the glass component 2, diboron trioxide (B₂O₃) , silica (SiO₂) , and diphosphorus pentoxide (P₂O₅) are components that form skeletons of glass. When a content of B₂O₃+SiO₂+P₂O₅ is excessively large, a dissolution property degrades. Thus, the content of B₂O₃+SiO₂+P₂O₅ is for example less than or equal to 90%, preferably less than or equal to 85%, and more preferably less than or equal to 80%. In order to improve a devitrification resistance, the content of B₂O₃+SiO₂+P₂O₅ is, for example, greater than or equal to 40%, and preferably greater than or equal to 45%. In order to enhance the chemical durability, SiO₂ is preferably contained, and the SiO₂ content is more preferably greater than or equal to 5%. In order to enhance the dissolution property, the SiO₂ content is preferably less than or equal to 70%, more preferably less than or equal to 60%, and especially preferably less than or equal to 50%. In order to lower a dissolution temperature, B₂O₃ is preferably contained. A B₂O₃ content is more preferably greater than or equal to 5%, and especially preferably greater than or equal to 10%. In order to suppress the occurrence of a phase splitting of glass, the B₂O₃ content is preferably less than or equal to 80%, and more preferably less than or equal to 75%.

In the glass composition 2, Li₂O, Na₂O, or K₂O may be contained in the glass in order to lower the dissolution temperature. However, when the content thereof is excessively large, the glass is liable to be devitrified. Thus, the content of Li₂O+Na₂O+K₂O is, for example, less than or equal to 30%, preferably less than or equal to 25%, and more preferably less than or equal to 20%.

In the glass composition 2, MgO, CaO, SrO, or BaO may be contained in the glass in order to lower the dissolution temperature. However, when the content thereof is excessively large, the glass is liable to be devitrified. Thus, the content of MgO+CaO+SrO+BaO is, for example, less than or equal to 20%, preferably less than or equal to 15%, and more preferably less than or equal to 10%.

The glass composition 2 may also contain the following components.

In the glass composition 2, zinc oxide (ZnO) is a component of the glass composition 2, and this component improves a meltability of glass, and lowers the glass transition temperature and the softening temperature. A ZnO content is, for example, less than or equal to 20%, preferably less than or equal to 15%, and more preferably less than or equal to 10%.

In the glass composition 2, dialuminum trioxide (Al₂O₃) is a component of the glass composition 2, and this component enhances the chemical durability, and suppresses the occurrence of a phase splitting of glass. When an Al₂O₃ content is less than or equal to 20%, an increase in the liquidus temperature is suppressed. The Al₂O₃ content is preferably less than or equal to 15%, and more preferably less than or equal to 10%.

In the glass composition 2, zirconium dioxide (ZrO₂) is an optional component of the glass composition 2, and this component enhances the chemical durability, and improves the devitrification resistance. When a ZrO₂ content is less than or equal to 15%, a degradation of the devitrification resistance due to an excessive content of ZrO₂ can be suppressed. The ZrO₂ content is preferably less than or equal to 10%, and more preferably less than or equal to 5%.

In the glass composition 2, because diantimony trioxide (Sb₂O₃) oxidizes glass, a Sb₂O₃ content is preferably small in order to enhance the deep-ultraviolet ray transmittance, e.g. less than or equal to 0.1%, more preferably less than or equal to 0.05%, and further preferably Sb₂O₃ is substantially not contained.

In the glass composition 2, in order to reduce an environmental load, preferably lead oxide (PbO) and diarsenic trioxide (As₂O₃) are substantially not contained, except for inevitable contaminating. Fluorine (F) is also preferably substantially not contained in the glass, in order to suppress a variation of optical characteristics or a striae, because fluorine exhibits a volatility.

Furthermore, the ultraviolet ray-transmitting glass according to the embodiment of the present application is preferably provided with the following features.

The ultraviolet ray-transmitting glass according to the present application, which is used in an optical system, is preferably provided with a high ultraviolet ray transmittance. An external transmittance can be expressed with indices of degrees of coloring, λ₇₀ and λ₅. The degree of coloring λ₇₀, a wavelength indicating the external transmittance of 70% for a glass plate with a thickness of 10 mm, is preferably less than or equal to 350 nm, more preferably less than or equal to 320 nm, especially preferably less than or equal to 305 nm, and most preferably less than or equal to 295 nm. Moreover, the degree of coloring λ₅, a wavelength indicating the external transmittance of 5% for a glass plate with a thickness of 10 mm, is preferably less than or equal to 245 nm, more preferably less than or equal to 240 nm, especially preferably less than or equal to 235 nm, and most preferably less than or equal to 230 nm.

According to the embodiment of the present application, by lowering the liquidus temperature of the ultraviolet ray-transmitting glass, an occurrence of a devitrification is suppressed when a molding product is molded from a glass melt, and thereby a productivity and a glass quality can be enhanced. The liquidus temperature is, for example, less than or equal to 1200° C., preferably less than or equal to 1150° C., and more preferably less than or equal to 1100° C. The liquidus temperature used in the specification of the present application refers to the minimum temperature at which a crystallized solid body is not formed from a glass melt, when held at a predetermined temperature for a predetermined period of time.

### <Manufacturing Method of Ultraviolet Ray-Transmitting Glass>

A manufacturing method of ultraviolet ray-transmitting glass according to the embodiment of the present application is a method of manufacturing the ultraviolet ray-transmitting glass according to the above-described embodiment. Basic operations in the manufacturing method of the ultraviolet ray-transmitting glass according to the present application are based on a conventionally known manufacturing method of glass, i.e. including melting a glass material or a glass cullet, and cooling the obtained glass melt, to solidify the glass melt. During the above-described process, in the embodiment of the present application, preferably, the iron content in the glass is reduced, and an oxidation/reduction state of the components included in the obtained glass is controlled, and thereby excellent ultraviolet ray transmission characteristics are obtained.

The prepared glass raw material of glass cullet is not particularly restricted, as long as the ultraviolet ray-transmitting glass according to the embodiment of the present application can be obtained. Examples of the raw material include, for example, nitrates, sulfates, carbonates, hydroxides, oxides, boric acid, or the like is used. A glass raw material, from which the above-described glass composition 1 or the above-described glass composition 2 can be obtained, is preferable.

The glass raw material or the glass cullet is heated at a temperature that is higher than the temperature, at which the glass raw material or the glass cullet is molten, so that the glass melt is obtained. The condition for melting in the process may include that the glass melt contacts with air atmosphere (oxidizing atmosphere) or the glass melt contacts with non-oxidizing atmosphere. In order to provide the non-oxidizing atmosphere, a method of introducing a non-oxidizing gas such as nitrogen or argon in a furnace, or a method of introducing a flame of a burner using a combustible gas that does not contain oxygen, such as city gas, into a furnace can be used.

When a reducing agent is contained in the glass raw material or a glass cullet, the reducing agent that remains in the obtained glass will be considered to be a glass raw material. The reducing agent that does not remain in the obtained glass will be considered to be an externally additive to the glass raw material. The reducing agent used in the embodiment of the present application and remaining in the glass includes tin oxides (SnO₂, SnO), silicon (Si), aluminum (Al), fluoride (aluminum fluoride, lanthanum fluoride, or the like), or the like. The reducing agent volatilized and not remaining in the glass includes carbon (C). Carbon can be added in a form of a carbon powder or a carbohydrate, such as sucrose.

In the case of using the reducing agent containing at least one species of tin oxide selected from among SnO₂ and SnO, a content of tin oxide to be added to the reducing agent, which is a total of SnO₂ and SnO, is preferably controlled so that the tin oxide content in glass is greater than 0.3 mass % and less than or equal to 3 mass %, when the melting process is performed under the air atmosphere. When the content is less than or equal to 0.3 mass %, the effect of enhancing the ultraviolet ray transmittance is insufficient. Tin oxide is preferably added so that the content is greater than or equal to 0.35 mass %, On the contrary, when the content is greater than 3 mass %, the transmittance may decrease. Thus, tin oxide is preferably added so that the content is less than or equal to 2 mass %, and more preferably added so that the content is less than or equal to 1 mass %.

On the other hand, in the case where the melting process is performed under the non-oxidizing atmosphere, the content of tin oxide to be added to the reducing agent, which is a total of SnO₂ and SnO, is preferably controlled so that the tin oxide content in glass is greater than 0 mass % and less than or equal to 0.3 mass %. When tin oxide is added so that the content is greater than 0 mass %, the ultraviolet ray transmittance can be further enhanced. Tin oxide is preferably added so that the content is greater than or equal to 0.01 mass %. On the contrary, when tin oxide is added so that the content is greater than or equal to 0.3 mass %, the transmittance may decrease. Thus, tin oxide is preferably added so that the content is less than or equal to 0.2 mass %, and more preferably added to that the content is less than or equal to 0.1 mass %.

In the case of using carbon (C) as the reducing agent, an amount of addition of carbon may be determined depending on an atmosphere in the glass melting process and a melting time of the process. For example, under the non-oxidizing atmosphere, preferably carbon of greater than or equal to 0.2 mass % and less than or equal to 1 mass % for 100 mass % of glass is externally added. Moreover, in this case, during the manufacturing process of glass, carbon becomes carbon dioxide and is volatilized. Thus, in the ultraviolet ray-transmitting glass obtained as above, carbon originated from the reducing agent is not left.

The molten glass obtained as above is cooled and solidified using a known method, and ultraviolet ray-transmitting glass is obtained. In the case where the ultraviolet ray-transmitting glass is provided in a form of a glass block, by performing machining processes such as grinding and polishing, a molding with a desired shape can be obtained. Moreover, in the case of pouring the molten glass into a molding die, and solidifying the glass by cooling, a molding with a desired shape given by the die can be obtained by removing the die. The glass molding obtained as above may be softened by heating again in the post processing, and molded by pressing a die against the softened glass molding with pressure.

When the LED element 3 is an UV-LED, the refractive index for the d-line of sapphire n_{d} is 1.77, and the refractive index for the d-line of aluminum nitride n_{d} is 2.1. Thus, the light emitting surface of the LED element 3 is formed of a material with a high refractive index. Then, in this case, both the optical member 4 and the adhesive layer 5 are preferably formed of ultraviolet ray-transmitting glass each with a high refractive index. In this case, B₂O₃—La₂O₃ based inorganic glass containing B₂O₃ and La₂O₃ as essential components has a high transmittance in the ultraviolet ray region, a high refractive index, and an excellent water resistance. Thus, the B₂O₃—La₂O₃ based inorganic glass is preferably used for the material of the optical member of the embodiment of the present application. The material with a high refractive index is preferably a material having the refractive index n_{d} of greater than or equal to 1.6, more preferably greater than or equal to 1.7, further preferably greater than or equal to 1.71, especially preferably greater than or equal to 1.72, and most preferably greater than or equal to 1.73.

### (Other Example of Configuration of the Light Emitting Device)

The above-described example of configuration, in which both the optical member 4 and the adhesive layer 5 are formed of a material with a high refractive index for the UV-LED element, has been described. However, when the thickness of the adhesive layer 5 is thinner than the wavelength of light emitted from the LED element 3, the refractive index is not to be high, and a material with a low refractive index may be used for the adhesive layer 5.

This is because when the adhesive layer 5 is sufficiently thin, even for light totally reflected at the interface between the LED element 3 and the adhesive layer 5, evanescent light thereof can be used. In this case, even when the adhesive layer 5 is formed of a material with a low refractive index, the light extraction efficiency can be enhanced to the extent where the adhesive layer 5 can be put to practical use. Thus, in this configuration, although the LED element 3 and the optical member member 4 are formed of a material with a high refractive index, the refractive index of the adhesive layer 5 having a thickness of several tens of nanometers to several hundreds of nanometers, which is less than the wavelength of emitted light, is not particularly restricted.

### (Manufacturing Method of the Light Emitting Device)

The light emitting device 1 according to the embodiment of the present application is manufactured as follows. First, an LED element 3 is formed on a substrate 2 using a known method, and an optical member 4 is prepared separately. Next, on an adhesive surface of the LED element 3 or the optical member 4, an inorganic glass layer to serve as an adhesive layer 5 is formed. The inorganic glass layer is softened by heating, and the optical member 4 or the LED element 3 to be bonded is brought into contact to the softened inorganic glass layer before solidification. Then, the inorganic glass is solidified by cooling, and thereby the adhesive layer 5 is obtained. Thus, the light emitting device 1 is obtained. In the process of forming the inorganic glass layer, a material of the adhesive layer 5 in the form of a frit paste is applied on the adhesive surface by using a known method, such as a screen printing, and a decalcification and a defoaming are performed by heating, and thereby the inorganic glass layer is formed. In this case, a thickness of the obtained adhesive layer 5 falls within a range from several tens of micrometers to several hundreds of micrometers. Moreover, the adhesive layer 5 may be also formed by preparing a green sheet of the materials of the adhesive layer 5, placing a small chip of the green sheet on the adhesive surface, and performing a decalcification and a defoaming by heating. In this case, a thickness of the obtained adhesive layer 5 falls within a range from several tens of micrometers to about 200 micrometers. Furthermore, the adhesive layer 5 may be also formed by preparing a plate of the materials of the adhesive layer 5, making the plate into a sheet by a redraw forming process, placing a small chip of the sheet on the adhesive surface, and heating the small chip so as to be fused to the adhesive surface. In this case, a thickness of the obtained adhesive layer 5 falls within a range from several tens of micrometers to about 200 micrometers.

Moreover, the adhesive layer 5 may be arranged using water glass. In this case, a water-soluble alkali metal silicate, known as water glass, is applied on the adhesive surface of the LED element 3 or the optical member 4, bringing the optical member 4 or the LED element 3, to be bonded to the adhesive surface, into contact with a part on which water glass is applied, and heating the part so as to form the adhesive layer 5 mainly contains a glassy material of Na₂SiO₃. Thus, the light emitting device 1 is obtained. In this case, the thickness of the adhesive layer 5 falls within a range from several tens of nanometers to several hundreds of nanometers.

### [Variations of the Embodiment of the Light Emitting Device]

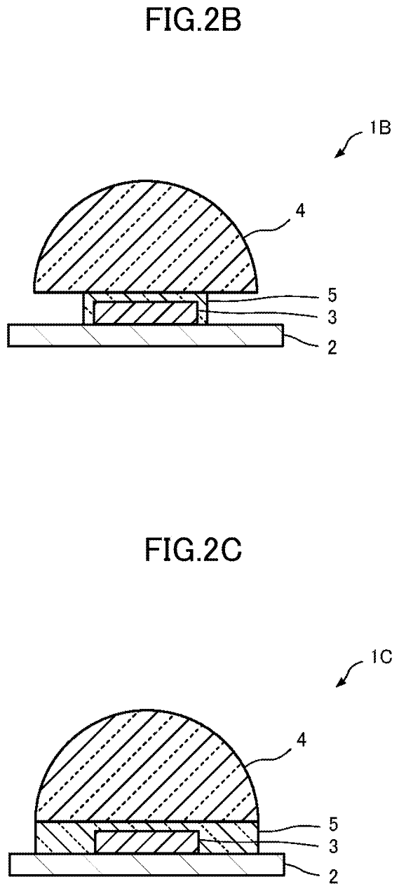

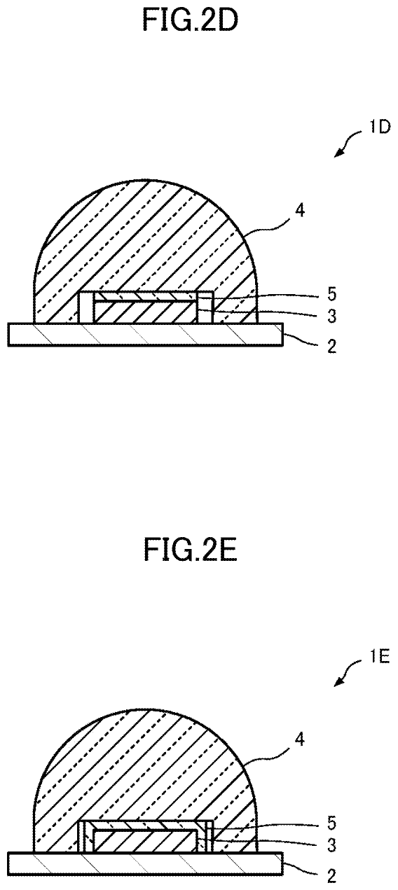

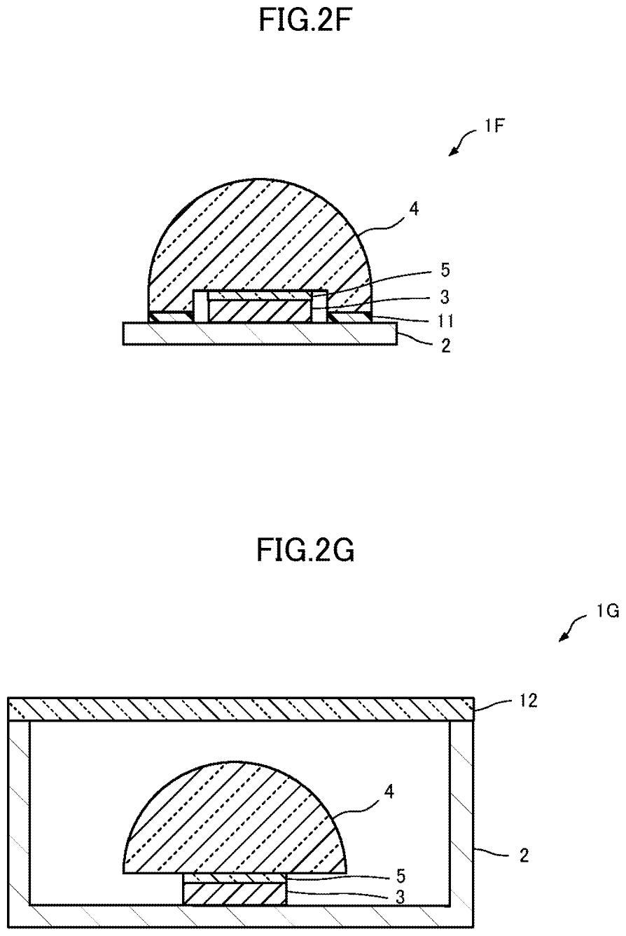

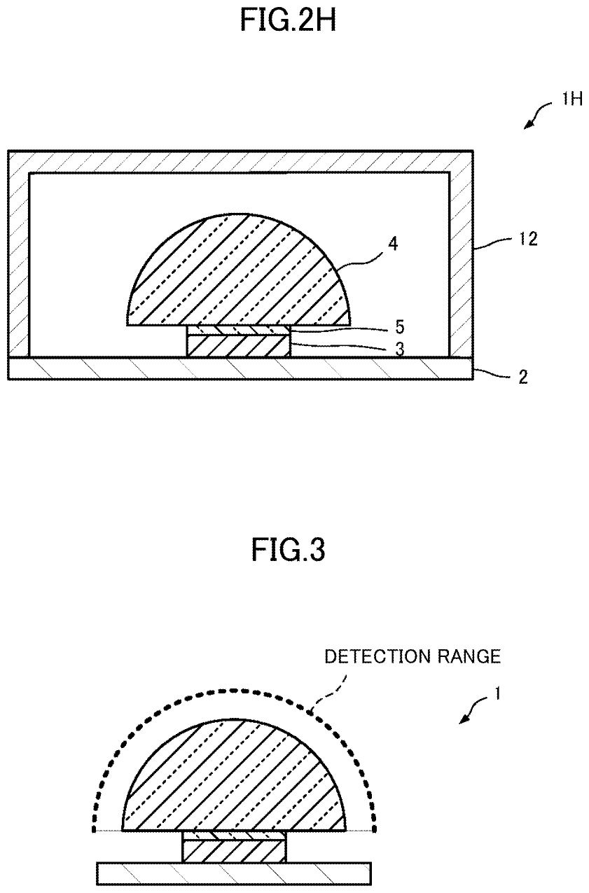

As described above, the light emitting device 1 according to the embodiment of the present application has been described with reference to FIG. 1. In addition to the light emitting device 1, variations of the embodiment will be described with reference to FIGS. 2A to 2H, as follows.

FIG. 2A depicts an example of a light emitting device 1A according to a first variation of the embodiment of the present application, in which the adhesive layer 5 is arranged over an entire surface of the optical member 4 on the adhesive layer side.

FIG. 2B depicts an example of a light emitting device 1B according to a second variation of the embodiment of the present application, in which the adhesive layer 5 is arranged not only on the adhesive surface of the LED element 3 but also a side surface of the LED element 3.

FIG. 2C depicts an example of a light emitting device 1C according to a third variation of the embodiment of the present application, in which the adhesive layer 5 fills a space between the substrate 2 and the optical member 4, while sealing the LED element 3.

FIG. 2D depicts an example of a light emitting device 1D according to a fourth variation of the embodiment of the present application, in which a peripheral portion of the optical member 4 is extended so as to be in contact with the substrate 2.

FIG. 2E depicts an example of a light emitting device 1E according to a fifth variation of the embodiment of the present application, obtained by combining FIG. 2B and FIG. 2D, in which the adhesive layer 5 is arranged not only on the adhesive surface of the LED element 3 but also side surfaces of the LED element 3, and a peripheral portion of the optical member 4 is extended so as to be in contact with the substrate 2.

FIG. 2F depicts an example of a light emitting device 1F according to a sixth variation of the embodiment of the present application, in which a peripheral portion of the optical member 4 is extended toward the substrate 2, and fixed to the substrate 2 via an adhesive layer 11.

FIG. 2G depicts an example of a light emitting device 1G according to a seventh variation of the embodiment of the present application, in which the substrate 2 has a shape of a container provided with side walls and a cover 12 made of glass. The cover 12 may be formed of a material through which light emitted from the LED element 3 is passed.

FIG. 2H depicts an example of a light emitting device 1H according to an eighth variation of the embodiment of the present application, in which a cover 12 having a shape of a lid provided with side walls made of glass is arranged on the substrate 2.

In the light emitting device 1A, in the process of forming the adhesive layer 5, because a raw material of the adhesive layer 5 is applied over the entire surface of the optical member 4 on the adhesive layer side, it is easy to form the adhesive layer 5.

In the light emitting devices 1B and 1C, because the adhesive layer also covers the side surfaces of the LED element, a substance that accelerates the degradation of the LED element such as an atmospheric moisture is prevented from entering from outside into the LED element, deterioration of performance of the LED element can be suppressed.

In the light emitting devices 1D and 1E, because a part of the optical member 4 is in contact with the substrate 2, the optical member 4 is prevented from falling off from the LED element. In the light emitting device 1F, because the optical member 4 is bonded also to the substrate 2, the adhesion of the optical member 4 to the LED element 3 becomes firmer, and thus an atmospheric moisture, or the like is prevented from entering from outside into the LED element and deterioration of performance of the LED element can be suppressed. The optical member 4 can be bonded to the substrate 2 using a conventional bonding method. For the adhesive layer 11, for example, an inorganic adhesive agent such as a metal solder, or a low melting point glass may be used. Moreover, because the adhesive layer 11 is located at a position that is not irradiated with high intensity light emitted from the LED element, an organic adhesive agent such as a silicone based adhesive agent may be used.

In the light emitting device 1G, the substrate has a shape of a box, and the LED element and the optical member are stored in the box. Moreover, a cover made of a material with a high transmittance at a wavelength of light emitted from the LED element, such a quartz or inorganic glass, is provided. The cover is bonded to the wall portion of the substrate via a metal solder, and thus prevents an atmospheric moisture, or the like from entering from outside and suppresses deterioration of performance of the LED element.

In the light emitting device 1H, the optical member and the LED element are separated from outside by the substrate and the cover, similarly to the light emitting device 1G. When the cover has a shape of a box, the substrate has a shape of a flat plate, and thus a cost for the expensive substrate can be reduced. Moreover, by using the cover having the shape of a box, different from the light emitting device 1G, light emitted from the LED element toward the side wall also can be extracted. The cover is bonded to the substrate via a metal solder, an inorganic adhesive agent, an organic adhesive agent, or the like.

### EXAMPLE

In the following, the present disclosure will be described with examples. However, the present disclosure is not limited to the examples.

### (Optical Member)

### [Examples of Manufacturing Processes: 1-1 to 1-4]

In order to obtain glasses having compositions shown in TABLE 2, raw materials such as nitride, sulfate, hydroxide, oxide, and boric acid, corresponding to compositions shown in TABLE 2 respectively, were weighed so as to obtain glasses having the compositions, mixed sufficiently, charged into a platinum crucible, and heated at a temperature of a range from 1150° C. to 1350° C. for 1.5 hours to 3 hours to be dissolved. The molten glass was poured into a preheated die, cooled, formed into a shape of a flat plate, maintained for four hours at a temperature near the glass transition temperature, and annealed to a room temperature at a cooling rate of −60° C./h.

For the glass obtained as above, a refraction index n_{d} at a wavelength of 587.56 nm (d-line), an absorption coefficient α (unit in mm⁻¹), a total iron oxide content (T-Fe₂O₃) (unit in mass ppm), a trivalent iron ion intensity, a glass transition temperature T_{g} (unit in ° C.), a degree of coloring (unit in nm), and a liquidus temperature (unit in ° C.) were measured. The methods of measuring the above-described values will be described as follows.

The refractive index was measured for a sample, which was processed into a shape of a rectangular parallelepiped having one side of greater than or equal to 5 mm, and a thickness of greater than or equal to 5 mm, using a precision refractometer (by Shimadzu Corporation, type: KPR-200, KPR-2000). The refractive index was measured for samples obtained by annealing at a temperature drop rate of −60° C./h.

The absorption coefficient was obtained by calculating based on the external transmittance measured for samples having thicknesses of 10 mm, 5 mm, and 1 mm, in which both surfaces were polished, using a spectrophotometer (by HITACHI High-Tech Science Corporation, type: U-4100). The absorption coefficient can be obtained from the external transmittance through the following relation:

lnT=−α×d+ln (1−r)²,

where lnT represents a natural logarithm of T, T represents the external transmittance, α represents the absorption coefficient, d represents a thickness of the sample, and r represents a single sided reflectance.

The degree of coloring was obtained by the wavelength λ₇₀ indicating the external transmittance of 70% and the wavelength λ₅ indicating the external transmittance of 5% read from measurement data of the external transmittance for the sample with the thickness of 10 mm.

The total iron oxide content (T-Fe₂O₃) was measured using an ICP mass spectrometry according to the following procedure. Pulverized glass, to which a mixed acid of hydrofluoric acid and sulfuric acid were added, was decomposed by heating. After the decomposition, hydrochloric acid was added to the decomposed glass, to be a predetermined amount. Then, a concentration of iron (Fe) was measured by using the ICP mass spectrometry. The iron concentration was corrected by using a calibration curve which was prepared using a standard solution. The total iron oxide content (T-Fe₂O₃) in glass was calculated based on the iron concentration obtained as above and an amount of the decomposed glass. For the ICP mass spectrometer, Agilent 8800 by Agilent Technologies Japan, Ltd. was used.

The trivalent iron ion Fe³⁺ intensity was measured using an electron spin resonance (ESR) method according to the following procedure. Pulverized glass of 0.3 g was weighed, and as an internal standard, a copper nitrate standard solution for ICP was added to the pulverized glass so that copper ion Cu²⁺ of 30 μg was added to the glass. The obtained sample was dried for about two hours at a temperature of about 50° C. Then, the sample was filled into a measurement tube for ESR, a measurement was performed, and an electron spin resonance spectrum was obtained. For the measurement, ESR spectrometer by JEOL Ltd. was used. Conditions for the ESR measurement are listed in TABLE 1.

For the ESR spectrum obtained by the measurement under the condition listed in TABLE 1, a trivalent iron ion Fe³⁺ signal intensity and a Cu²⁺ signal intensity are defined according to relations shown below.

Fe³⁺ signal intensity=(maximum value of the signal intensity of an Fe³⁺ peak appearing at around a magnetic field of 157 mT)−(minimum value of the signal intensity of the Fe³⁺ peak appearing at around a magnetic field of 157 mT), and

Cu²⁺ signal intensity =(maximum value of the signal intensity of a Cu²⁺ peak appearing at around a magnetic field of 310 mT)−(minimum value of the signal intensity of the Cu²⁺ peak appearing at around a magnetic field of 310 mT).

Furthermore, the Fe³⁺ intensity is defined based on the Fe³⁺ signal intensity and the Cu²⁺ signal intensity, removing variations in amplification factors in the measurement and variations in measurement intensities:

Fe³⁺ intensity=(Fe³⁺ signal intensity/amplification factor in the measurement of Fe³⁺ signal intensity)/(Cu²⁺ signal intensity/amplification factor in the measurement of Cu²⁺ signal intensity).

TABLE 1

| | Fe | Cu | |
|---|---|---|---|
| Frequency | 9.436 | 9.436 | GHz |
| Power | 4 | 4 | mW |
| C. Field | 330 | 330 | mT |
| Sw Wid (±) | 250 | 250 | mT |
| Sw Time | 2 | 2 | min |
| Mod Wid | 0.63 | 0.63 | mT |
| Amp | 500 | 20 | |
| Time C | 0.1 | 0.1 | sec |

The glass transition temperature T_{q} was obtained by performing the measurement for a sample processed into a cylindrical shape with a diameter of 5 mm and a length of 20 mm by using a Thermomechanical Analyzer (by Rigaku Corporation, type: Thermo Plus TMA8310) at a temperature rising rate of 5° C./min.

The liquidus temperature was obtained as follows. A sample was left to stand on a dish made of platinum in an electric furnace set at a constant temperature for one hour. Then, the heated sample was observed using an optical microscope of 50 magnifications. The minimum temperature, at which crystal deposition was not observed, was determined to be the liquidus temperature.

Hemispherical glass lenses are obtained as follows. Glass melt having the composition listed in TABLE 2 was caused to be dropped from a pipe attached to a glass melting furnace. The dropped glass melt was solidified by cooling, and a glass rough ball having a roughly spherical shape was obtained. Then, a surface of the glass rough ball was polished, and thereby a glass polished ball was obtained. Moreover, the glass polished ball also can be obtained by using another method. That is, a glass block was prepared by performing mechanical processing using a blade, or the like for a glass plate obtained by molding and solidifying the glass melt in a shape of a plate, and by heating again and deforming. Then, a surface of the glass block was polished by a ball polisher, and thereby the glass polished ball was obtained. The glass polished ball, obtained as above, was processed into a shape of a hemisphere by slicing or polishing, and thereby the hemispherical glass lenses formed of glasses having the compositions of the examples of manufacturing processes 1-1 to 1-4 were obtained.

TABLE 2

| | | | Example of manufacturing process | | | |
|---|---|---|---|---|---|---|
| | | | 1-1 | 1-2 | 1-3 | 1-4 |
| Composition | | SiO₂ | 5.61 | 5.83 | 5.83 | 5.82 |
| (mol %) | | B₂O₃ | 73.44 | 66.59 | 66.59 | 66.58 |
| | | Li₂O | 13.47 | | | |
| | | MgO | 7.48 | | | |
| | | La₂O₃ | | 19.29 | 19.29 | 19.28 |
| | | Y₂O₃ | | 8.29 | 8.29 | 8.29 |
| | | SnO₂ | 0.01 | | | 0.03 |
| | | Total | 100 | 100 | 100 | 100 |
| Refractive | | n_{d} | 1.53 | 1.74 | 1.74 | 1.74 |
| index | | | | | | |
| Absorption | | 400-1000 | Less | Less | Less | Less |
| coefficient | | nm | than | than or | than or | than or |
| α [mm⁻¹] | | | 0.001 | equal to | equal to | equal to |
| | | | | 0.003 | 0.002 | 0.001 |
| | | 400 nm | Less | 0.003 | 0.002 | 0.001 |
| | | | than | | | |
| | | | 0.001 | | | |
| | | 360 nm | Less | 0.011 | 0.005 | 0.001 |
| | | | than | | | |
| | | | 0.001 | | | |
| | | 310 nm | 0.001 | 0.061 | 0.016 | 0.008 |
| | | 260 nm | 0.018 | 0.168 | 0.063 | 0.033 |
| T-Fe₂O₃ | | | 0.8 | 1.9 | 0.8 | 0.8 |
| [mass ppm] | | | | | | |
| Fe³⁺ intensity | | | 0.0055 | 0.0329 | 0.0112 | 0.0059 |
| Glass transition | | | 550 | 685 | 685 | 685 |
| temperature | | | | | | |
| [° C.] | | | | | | |
| Degree of | λ₇₀ | | 249 | 344 | 303 | 275 |
| coloring | λ₅ | | Less | 243 | 233 | 215 |

| | | | | |
|---|---|---|---|---|
| [nm] | than | | | |
| | 215 | | | |
| Liquidus | Less | 1070 | 1070 | 1070 |
| temperature | than or | | | |
| [° C.] | equal to | | | |
| | 1100 | | | |

### (Adhesive Layer)

### [Examples of Manufacturing Process: 2-1 to 2-3]

In order to obtain glasses having compositions shown in TABLE 3, raw materials such as nitride, sulfate, hydroxide, oxide, and boric acid, corresponding to compositions shown in TABLE 3, were weighed so as to obtain glasses having the compositions, mixed sufficiently, charged into a platinum crucible, and heated at a temperature of a range from 1150° C. to 1200° C., for 1.5 to 3 hours to be dissolved. The molten glass was poured into a preheated die, cooled, formed into a shape of a flat plate, maintained for four hours at a temperature near the glass transition temperature, and annealed to a room temperature at a cooling rate of −60° C./h.

For the glass obtained as above, a refractive index n_{d} at a wavelength of 587.56 nm (d-line), an absorption coefficient (unit in mm⁻¹), and a glass transition temperature T_{g} (unit in ° C.) were measured. The methods of measuring the above-described values will be described as follows.

The refractive index was measured for a sample, which was processed into a shape of a rectangular parallelepiped having one side of greater than or equal to 5 mm, and a thickness of greater than or equal to 5 mm, using a precision refractometer (by Shimadzu Corporation, type: KPR-200, KPR-2000). The refractive index was measured for samples obtained by annealing at a temperature drop rate of −60° C./h.

The absorption coefficient was obtained by calculating based on the external transmittance measured for samples having a thickness of 10 mm, 5 mm, and 1 mm, in which both surfaces were polished, using a spectrophotometer (by HITACHI High-Tech Science Corporation, type: U-4100). The absorption coefficient can be obtained from the external transmittance through the following relation:

lnT=−α×d+ln (1−r)²,

where lnT represents a natural logarithm of T, T represents the external transmittance, a represents the absorption coefficient, d represents a thickness of the sample, and r represents a single sided reflectance.

The glass transition temperature T_{g} was measured by using a differential thermal analyzer (DTA).

TABLE 3

| | | Example of manufacturing process | | |
|---|---|---|---|---|
| | | 2-1 | 2-2 | 2-3 |
| Composition | SiO₂ | 30 | 15 | |
| (mol %) | B₂O₃ | 45 | 30 | |
| | P₂O₅ | | | 35 |
| | Na₂O | 5 | | |
| | K₂O | 5 | | |
| | BaO | | 10 | |
| | ZnO | 15 | 35 | 5 |
| | SnO | | | 60 |
| | Bi₂O₃ | | 10 | |
| | Total | 100 | 100 | 100 |
| Refractive | n_{d} | 1.52 | 1.79 | 1.83 |
| index | | | | |
| Absorption | 400-1000 | Less than | Less than | Less than |
| coefficient | nm | or equal to | or equal to | or equal to |
| α [mm⁻¹] | | 0.002 | 0.228 | 0.012 |
| | 400 nm | 0.002 | 0.228 | 0.012 |
| | 360 nm | 0.006 | 2.817 | 0.312 |
| | 310 nm | 0.041 | 6.218 | 5.828 |
| | 260 nm | 0.240 | >7 | >6 |
| Glass transition | | 470 | 500 | 280 |
| temperature [° C.] | | | | |

### <Composition and Characteristics of the Adhesive Layer Glass>

For forming the adhesive layer on the surface of the hemispherical glass lens on the adhesive layer side, various conventional methods can be used. For example, a method of screen-printing a material of the adhesive layer in a form of a glass frit paste on the adhesive surface of the optical member; a method of attaching a glass sheet prepared by performing a redraw forming process, a press forming process, and a slicing processing to the optical member; or a method of pressing a small piece of glass placed on the adhesive surface of the optical member to form the piece into a sheet shape, can be employed to form the adhesive layer. A thickness of the adhesive layer fell within a range from 20 μm to 500 μm.

### First to Third Examples

Three hemispherical glass lenses obtained by performing the above-described example of a manufacturing process 1-4 were prepared, and the adhesive layers according to the examples of manufacturing processes 2-1 to 2-3 were placed on the corresponding flat surface sides of the hemispherical glass lenses. Then, the hemispherical glass lenses were arranged so that the surfaces, on which the adhesive layers were placed, were in contact with the LED elements, and the adhesive layers were heated at a temperature higher than the glass transition temperature of the adhesive layers by 20 to 100° C. for 5 to 15 minutes, and thereby the hemispherical glass lenses were bonded to the LED elements. During the above-described treatment, by applying a load to the hemispherical glass lenses, the heating temperature could be made lower than that without applying a load. Thus, light emitting devices of the first to third examples were prepared.

### Fourth Example

In the fourth example, a hemispherical glass lens obtained by performing the above-described example of the manufacturing process 1-4 was prepared, and water glass (aqueous solution of sodium silicate) was applied on at least one of the flat surface side of the hemispherical glass lens and the light emitting surface of the LED element, and the hemispherical glass lens and the LED element were arranged so that the flat surface and the light emitting surface were in contact with each other. By heating at a temperature of 200 to 300° C., the adhesive layer was dehydrated and solidified to bond the hemispherical glass lens to the LED element, and the light emitting device was manufactured. Thus, a light emitting device of the fourth example was prepared. The water glass dehydrated and solidified as above was sodium silicate glass, and absorption of light with a wavelength of greater than or equal to 200 nm by the adhesive layer was not observed. Various types of inorganic adhesive agents can be used, as long as the adhesive agents do not absorb light with the wavelength used by the LED element.

Then, the hemispherical glass lens can be bonded to the LED element similarly to the water glass by using an aqueous solution of orthophosphate or silica sol in which anhydrous silicate fine particles are dispersed in water.

### Fifth Example

Although the bonding technique of a surface activation bonding has been known, this technique cannot be used for bonding inorganic glass. In the fifth example, a nitride layer (e.g. AlN or SiN) was deposited on the flat surface side of the hemispherical glass lens obtained by performing one of the above-described examples of manufacturing processes 1-1 to 1-4. Then, the flat surface of the hemispherical glass lens and the light emitting surface of the LED element were bonded to each other according to the surface activation bonding, and the light emitting device was manufactured. Thus, the light emitting device of the fifth example was provided. In order to enhance a bonding strength, both a surface roughness of the adhesive surface of the optical member and a surface roughness of the light emitting surface of the LED element are preferably low. The surface roughness Ra is preferably less than or equal to 1 nm.

The above-described first to fifth examples are practical examples. In the practical examples, the LED elements had flip-chip structures, in which the light emitting surface was a mirror surface of the base made of sapphire. Moreover, in the case of using the LED element in which the light emitting surface is a surface of the base made of aluminum nitride, the optical member can be bonded to the LED element according to the same process.

The effect of enhancing the light extraction efficiency obtained by the above-described light emitting devices was verified based on results of calculations for outputs of light extracted from the LED element to the outside of the element according to optical simulations. For the LED element, the optical member, and the adhesive layer, parameters listed in TABLES 4 and 5 were used. For the sixth and seventh examples, which will be described below, and the above-described third and fourth examples, outputs of light emitted from the light emitting device were calculated by using a ray tracing method. In particular, for the fourth example, in which the thickness of the adhesive layer is less than the wavelength of the emission light, an optical interference effect in the adhesive layer was taken into consideration in the calculation by using an optical interference calculation method. Computational model for the LED element and characteristics of the optical member and the adhesive layer, used in the simulation, are shown in TABLES 4 and 5, respectively. For estimating the outputs of emitted light, events of detection of light extracted above the light emitting surface of the LED element were counted. The detection range of light in this estimation is shown by a dashed curve in FIG. 3. The range is depicted as a cross section in FIG. 3, and has a shape of a hemispherical surface. TABLE 6 shows the calculational model of the light emitting device, and results of the optical simulations.

A light emitting device of the sixth example includes an LED element but is not provided with an optical member and an adhesive layer. Moreover, for a light emitting device of the seventh example, a hemispherical glass lens obtained by performing the above-described manufacturing process 1-4 was arranged so as to be in contact with an LED element via fluororesin, which is often used as an adhesive agent for an ultraviolet ray LED, on a flat surface side of the hemispherical glass lens, and the hemispherical glass lens and the LED element were bonded to each other. Thus, the light emitting device of the seventh example is obtained.

Furthermore, an enhancement factor is defined as a ratio of outputs of light emitted from the light emitting device of each example to outputs of emission light of the sixth example. That is, the enhancement factor represents the degree of enhancement in the light extraction efficiency with respect to the light emitting device of the sixth example. In the simulation, the enhancement factors at wavelengths of emission light of 360 nm and 310 nm were calculated. Moreover, the seventh example is a comparative example. In the light emitting device of the seventh example, fluororesin, which is often used as an adhesive agent for an ultraviolet ray LED, was used in the adhesive layer. According to this configuration, while the ratio d/λ is greater than or equal to 1, the refractive index of the adhesive layer n_{d(A)}, of the seventh example, is small, i.e. the refractive index n_{d(A)} is less than 1.5.

TABLE 4

| | |
|---|---|
| Size of LED element | 1 square mm |
| Thickness of sapphire base | 100 μm |
| Film thickness of light emitting | 10 μm |
| layer | |
| Contact layer (back surface of | Complete absorber |
| LED) | |

TABLE 5

| | | | | Example of | Example of |
|---|---|---|---|---|---|
| | | | | manufactur- | manufactur- |
| | | | | ing | ing |
| | | Sodium | | process | process |
| | | silicate | Fluororesin | 1-4 | 2-3 |
| Refractive index | | 1.495 | 1.35 | 1.74 | 1.83 |
| Absorption | 360 nm | 0 | 0 | 0.001 | 0.312 |
| coefficient | 310 nm | 0 | 0 | 0.008 | 5.828 |

α [mm⁻¹]

TABLE 6

| | Example 6 | Example 7 | Example 3 | Example 4 |
|---|---|---|---|---|
| Optical | None | Example of | Example of | Example of |
| member: | | manufacturing | manufacturing | manufacturing |
| material | | process | process | process |
| | | 1-4 | 1-4 | 1-4 |
| Optical | None | Hemispherical | Hemispherical | Hemispherical |
| member: | | lens | lens | lens |
| shape | | 3.5 mmϕ | 3.5 mmϕ | 3.5 mmϕ |
| Adhesive | None | fluororesin | Example of | Sodium |
| layer: | | | manufacturing | silicate |
| material | | | process | |
| | | | 2-3 | |
| Adhesive | None | 30 μm | 30 μm | 100 nm |

The enhancement factor of the third and fourth examples are found to be greater than or equal to 2, indicating that according to the optical member and the adhesive layer provided in the light emitting device the outputs of the emission light are enhanced by double or more. The light emitting device of the third example is provided with the adhesive layer with a high refractive index and a low absorption coefficient, which suppresses an occurrence of a total reflection at the light emitting surface of the LED element. The light emitting device of the fourth example is provided with the adhesive layer with the thickness which is less than the wavelength of the emission light. According to the configuration, light can be guided to the optical member through evanescent light, a total reflection is prevented from occurring at the light emitting surface of the LED element. In the seventh example, due to the low refractive index of the adhesive layer, the occurrence of a total reflection at the interface between the adhesive layer and the LED element cannot be suppressed sufficiently, and the enhancement factor is about 1.6 at the most. The enhancement factor is preferably greater than or equal to 1.7.

### Eighth Example

In the eighth example, aluminum (Al) oxide, as the metal oxide, was deposited with a thickness of about 10 nm by using a sputtering method on the flat surface side of the hemispherical glass lens obtained by performing one of the above-described examples of manufacturing processes 1-1 to 1-4 and on the light emitting surface of the LED element. Then, the flat surface of the hemispherical glass lens and the light emitting surface of the LED element were bonded to each other by bringing the flat surface and the light emitting surface into contact with each other, and the light emitting device was manufactured. Thus, the light emitting device of the eighth example was provided. The bonding strength of the surfaces estimated by using a blade insertion method was 0.62 J/m². The metal oxide layer may be deposited only on either the flat surface of the optical member or the light emitting surface of the LED element, for bonding. The thickness of the metal oxide layer is preferably about 5 to 200 nm. In order to enhance the bonding strength, both a surface roughness of the adhesive surface of the optical member and a surface roughness of the light emitting surface of the LED element are preferably low. The surface roughness Ra is preferably less than or equal to 1 nm. Heating treatment during the bonding process or after the bonding process further enhances the bonding strength. A heating temperature is preferably 100 to 250° C. Oxide of silicon (Si), aluminum (Al), zirconium (Zr), or the like may be used for the metal oxide. Moreover, conventional deposition method, such as the sputtering method, an atomic layer deposition (ALD) method, or an evaporation method may be used for the deposition of the metal oxide layer.

As described above, the light emitting devices of the practical examples of the present application are found to have an excellent light extraction efficiency, include the adhesive layer, which is prevented from deteriorating by light emitted from the light emitting element, have a long life, and provide an effective use of light.

What is claimed is:

1. An optical member with an adhesive layer comprising:
the optical member formed of inorganic glass through which light passes; and
the adhesive layer formed of an inorganic material or a metal oxide, the inorganic material including inorganic glass or nitride.

2. The optical member with the adhesive layer according to claim 1, wherein the light is an ultraviolet ray with a wavelength greater than or equal to 200 nm and less than or equal to 400 nm.

3. The optical member with the adhesive layer according to claim 1, wherein a refractive index n_{d(O)} of the optical member for a d-line (587.6 nm) is greater than or equal to 1.5.

4. The optical member with the adhesive layer according to claim 1, wherein
the optical member is formed of transparent inorganic glass, and
an absorption coefficient α (mm⁻¹) of the optical member at a wavelength of the light is less than or equal to 0.2 mm⁻¹.

5. The optical member with the adhesive layer according to claim 1, wherein
an absorption coefficient α (mm⁻¹) of the adhesive layer at a wavelength of the light is less than or equal to 8 mm⁻¹.

6. The optical member with the adhesive layer according to claim 1, wherein
d/λ is less than 1, where d is a thickness of the adhesive layer and λ is a wavelength of the light.

7. The optical member with the adhesive layer according to claim 1, wherein
d/λ is greater than or equal to 1, where d is a thickness of the adhesive layer and λ is a wavelength of the light, and
wherein a refractive index n_{d(A)} of the adhesive layer for a d-line (587.6 nm) is greater than or equal to 1.5.

8. The optical member with the adhesive layer according to claim 7, wherein
Δn_{d}=|n_{d(O)}−n_{d(A)}| is less than or equal to 0.2, where an absolute value Δn_{d} of an absolute value of a difference between a refractive index n_{d(O)} of the optical member for the d-line and the refractive index n_{d(A)} of the adhesive layer for the d-line.

9. The optical member with the adhesive layer according to claim 1, wherein
a refractive index n_{d(O)} of the optical member for a d-line (587.6 nm) is greater than or equal to 1.6,
an absorption coefficient α (mm⁻¹) of the optical member at a wavelength of the light is less than or equal to 0.2 mm⁻¹, and
the optical member is formed of B₂O₃—La₂O₃ based inorganic glass containing diboron trioxide (B₂O₃) and dilanthanum trioxide (La₂O₃) as chemical components.

10. The optical member with the adhesive layer according to claim 1, wherein
the inorganic glass forming the optical member contains dibismuth trioxide (Bi₂O₃), titanium dioxide (TiO₂), tungsten trioxide (WO₃) and digadolinium trioxide (Gd₂O₃), a content of each being less than or equal to 3 mol % in terms of oxide.

11. The optical member with the adhesive layer according to claim 10, wherein
the inorganic glass forming the optical member further contains at least one species of tin oxide selected from among tin (II) oxide (SnO) and tin (IV) oxide (SnO₂), a content of each being less than or equal to 3 mol % in terms of oxide.

12. The optical member with the adhesive layer according to claim 10, wherein
the inorganic glass forming the optical member further contains diniobium pentaoxide (Nb₂O₅), a content of diniobium pentaoxide being less than or equal to 3 mol % in terms of oxide.

13. The optical member with the adhesive layer according to claim 10, wherein
the inorganic glass forming the optical member further contains ditantalum pentaoxide (Ta₂O₅), a content of ditantalum pentaoxide being less than or equal to 3 mol % in terms of oxide.

14. The optical member with the adhesive layer according to claim 1, wherein
a total content of diiron trioxides (T-Fe₂O₃) of the inorganic glass forming the optical member, obtained by converting iron oxides (FeO and Fe₂O₃) into diiron trioxide (Fe₂O₃), is less than or equal to 10 mass ppm.

15. The optical member with the adhesive layer according to claim 1, wherein
a trivalent iron ion Fe^{3'} intensity of the inorganic glass forming the optical member measured by an electron spin resonance (ESR) method is less than or equal to 0.0400.

16. A light emitting device comprising:
a substrate;
a light-emitting diode (LED) element arranged on the substrate; and
the optical member with the adhesive layer according to claim 1, wherein
the adhesive layer is arranged between the LED element and the optical member.

17. The light emitting device according to claim 16, wherein
the light emitting device has a flip-chip structure or a vertical type structure.

18. The light emitting device according to claim 16, wherein
the adhesive layer covers a side surface of the LED element.

19. The light emitting device according to claim 16, wherein
the optical member is in contact with the substrate, or the optical member is bonded to the substrate.

20. The light emitting device according to claim 16, wherein
a ratio (P1/P2) of outputs of light emitted from the light emitting device (P1) to outputs of light emitted from a device obtained by removing the optical member and the adhesive layer from the light emitting device (P2) is greater than or equal to 1.7.
